(19) United States
(12) Patent Application Publication
(10) Pub. No.: US 2026/0005043 A1
(43) Pub. Date: Jan. 1, 2026

(54) IN-LINE WAFER POSITIONING SYSTEM USING IR IMAGING

(71) Applicant: Applied Materials, Inc., Santa Clara, CA (US)

(72) Inventors: Yi Kun Kelvin Goh, Singapore (SG); Han Yan Koh, Singapore (SG); Kok Keong Lim, Singapore (SG)

(73) Assignee: Applied Materials, Inc., Santa Clara, CA (US)

(21) Appl. No.: 18/755,192

(22) Filed: Jun. 26, 2024

(51) Int. Cl. H01L 21/67; H01L 21/677; H01L 21/687

(52) U.S. Cl. CPC H01L 21/67115; H01L 21/67167; H01L 21/67196; H01L 21/67742; H01L 21/68742

(57) ABSTRACT

Monitoring system for a semiconductor manufacturing processing tool and methods of monitoring a semiconductor manufacturing process tool are described. The monitoring system has a reflector positioned above a transfer robot in a transfer station of the processing tool. The reflector is configured to direct radiant energy from a processing chamber connected to the transfer station to a camera above the transfer station, the camera configured to measure infrared radiation from the processing chamber.

### TECHNICAL FIELD

Embodiments of the disclosure generally relate to wafer positioning systems for semiconductor manufacturing processing chambers. In particular, embodiments of the disclosure relate wafer positioning systems for semiconductor manufacturing using in-line infrared (IR) radiation.

### BACKGROUND

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, tolerances for individual layer non-uniformity decreases. Slight deviations in the wafer alignment and tilt inside the processing chamber can affect film uniformity but may also affect loading/unloading processes by creating a hazard to movement of the transfer robots.

When a wafer or lift pin breaks inside the processing chamber, there is often a change in the orientation or tilt of at least a portion of the wafer. When this occurs, the transfer robot can crash into the broken wafer or broken lift pins during production causing extended recovery time to the affected chambers. Damage to the processing chamber and/or the transfer robot can result in breaking vacuum for the entire process tool to allow the chamber components to be cleaned and replaced including the transfer station that the transfer robot is located within. Current wafer alignment approaches utilize a top-down view to determine the wafer position. However, the top-down view is not always capable of predicting the presence of a physical hazard that might affect the transfer robot.

Therefore, there is a need in the art for apparatus and methods to prevent the transfer robot from crashing into broken wafers and/or broken lift pins within the processing chamber.

### SUMMARY OF THE CLAIMS

One or more embodiments of the disclosure are directed to a monitoring system for a semiconductor manufacturing processing tool. The monitoring system comprises: a reflector positioned above a transfer robot in a transfer station of the processing tool, the reflector configured to direct radiant energy from a processing chamber connected to the transfer station to a camera above the transfer station, the camera configured to measure infrared radiation from the processing chamber.

Additional embodiments of the disclosure are directed to a method of preventing damage to a transfer robot of a processing chamber, the method comprising: taking an infrared image of a processing chamber interior, the image including a wafer and lift pins; evaluating the image to determine if the processing chamber is in an operational state or a failure state from the image of the wafer and lift pins; and activating an interlock if the processing chamber is determined to be in a failure state.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The shading used in the Figures is for descriptive purposes only and should not be taken as referring to a particular material of construction. The cross-hatching patterns are solely chosen to help illustrate the different components and unless otherwise noted, the various materials of construction of the different components can be the same or different.

FIG. 1 illustrates a semiconductor manufacturing processing tool according to one or more embodiment of the disclosure;

FIG. 2 illustrates a schematic representation of a portion of a semiconductor manufacturing processing tool with a monitoring system according to one or more embodiments of the disclosure;

FIG. 3A illustrates an infrared image illustrating an exemplary processing chamber in an operational state as measured by a monitoring system according to one or more embodiments of the disclosure;

FIG. 3B illustrates a schematic representation of a top view of the processing chamber in which the image of FIG. 3A is taken showing the field of view of the camera and a centered and symmetrical triangular lift pin pattern;

FIG. 4 illustrates an infrared image showing a broken wafer in the processing chamber indicating a failure state as measured by a monitoring system according to one or more embodiment of the disclosure;

FIG. 5 illustrates an infrared image showing a broken lift pin in the processing chamber without a wafer indicating a failure state as measured by the monitoring system according to one or more embodiment of the disclosure;

FIG. 6 illustrates an infrared image showing a wafer on a broken lift pin in the processing chamber indicating a failure state as measured by the monitoring system according to one or more embodiment of the disclosure;

FIG. 7 illustrates an infrared image showing an off-center wafer in the processing chamber indicating a failure state as measured by the monitoring system according to one or more embodiment of the disclosure;

FIG. 8A. illustrates an infrared image illustrating an exemplary processing chamber in an operational state with an un-centered and/or asymmetrical lift pin arrangement as measured by a monitoring system according to one or more embodiments of the disclosure; and

FIG. 8B illustrates a schematic representation of a top view of the processing chamber in which the image of FIG. 8A is taken showing the field of view of the camera and a un-centered and/or asymmetrical triangular lift pin pattern.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more embodiments of the disclosure are directed to in-line wafer position detection systems using infrared (IR) radiation from heated silicon wafers and chamber background to determine wafer position while wafer transport is ongoing within the processing tool. Some embodiments of the disclosure detect positional irregularities and stops motion before any damage is done.

Embodiments of the disclosure use the differences between IR emissions from the wafer and chamber contents to interpret problems such as wafer displacement, breakage and a broken lift pin. The in-line wafer position detection system of some embodiments uses IR radiation from the heated silicon wafers and chamber background to determine wafer position while wafer transport is ongoing within the processing tool. The system of some embodiments detects positional irregularities and stops motion of the wafer transport system before any additional damage occurs.

One or more embodiments of the disclosure are directed to real-time monitoring of wafer movements which reduce the risk of equipment damage and risk to equipment up-time. In some embodiments, the system does not require additional light energy input for illumination, which might affect the process or chamber. Indirect detection away from the chamber, as used in some embodiments, does not occupy valuable space above the chamber, which usually has process critical equipment. The distance from the chamber reduces interference and is non-invasive, making retrofits and maintenance easier to implement.

In some embodiments, a line-of-sight between the IR camera and chamber interior is established through installation of a reflective setup on the inside of the transfer station. The reflective setup of some embodiments redirects IR radiation emitted from the chamber contents/components into the IR camera's viewable aperture. The camera of some embodiments is linked to a controller or processing computer that would determine if the wafer is in its intended position, or if there are issues with lift pins, for example, if the wafer was not in the intended position or if one of the lift pins had broken. In some embodiments, if the wafer is found to be out of position or shape, the system would link with the chamber interlock to stop the motion of the transfer robot to prevent the robot being damaged.

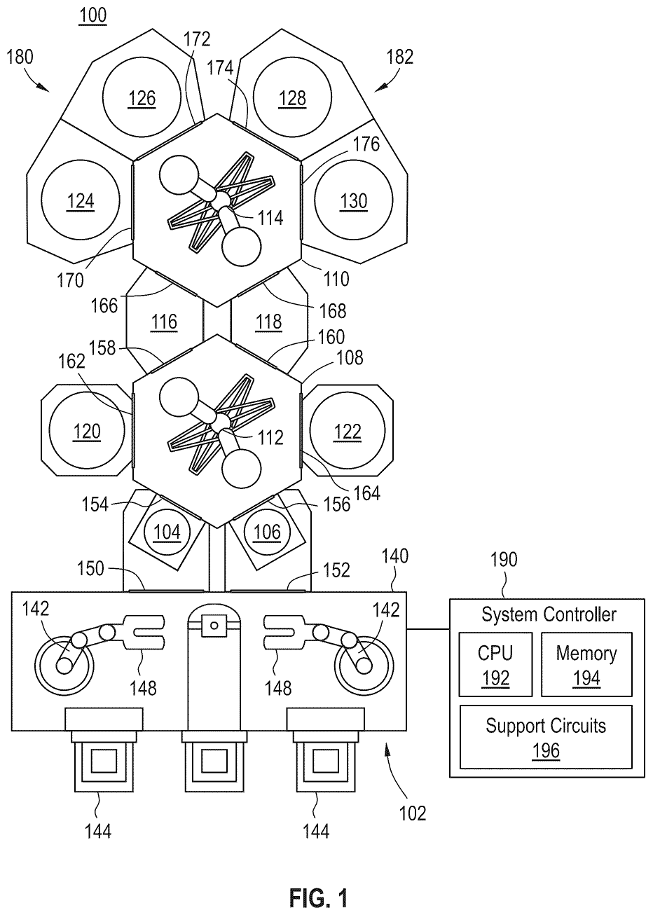

FIG. 1 is a schematic top-view diagram of an exemplary semiconductor manufacturing processing tool 100 according to one or more embodiments of the disclosure. The processing tool 100 is also referred to as a multi-chamber processing system or a cluster tool. The semiconductor manufacturing processing tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the semiconductor manufacturing processing tool 100 can be processed in and transferred between the various chambers without exposing the wafers to an ambient environment exterior to the semiconductor manufacturing processing tool 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the semiconductor manufacturing processing tool 100. Accordingly, the semiconductor manufacturing processing tool 100 may provide for an integrated solution for some processing of wafers, e.g., semiconductor substrates.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some embodiments, the processing chamber 120 can be capable of performing an annealing process, the processing chamber 122 can be capable of performing a cleaning process, and the processing chambers 124, 126, 128, 130 can be capable of performing epitaxial growth processes. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a preclean chamber. The processing chamber 120 may be an etch chamber.

A system controller 190 is coupled to the processing tool 100 for controlling the processing tool 100 or components thereof. For example, the system controller 190 may control the operation of the processing tool 100 using a direct control of the chambers 104, 106, 108, 116, 118, 110, 120, 122, 124, 126, 128, 130 of the processing tool 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing tool 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

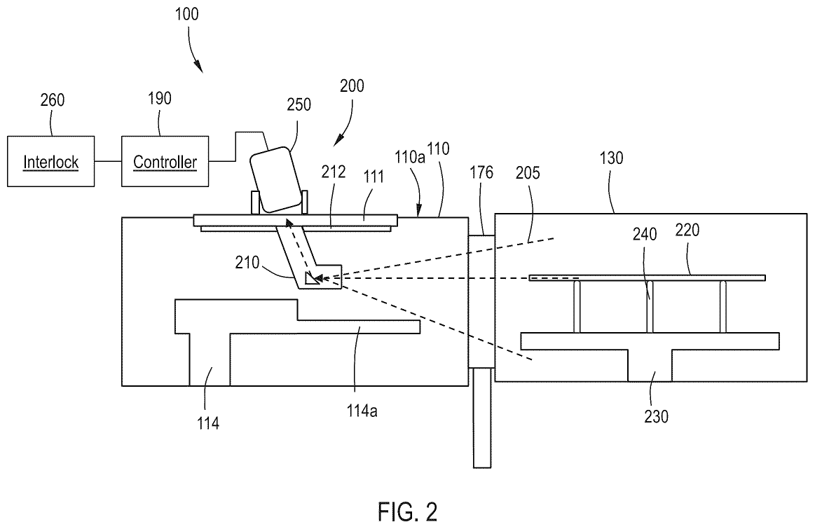

FIG. 2 illustrates a schematic representation of a portion of a semiconductor manufacturing processing tool 100 with a monitoring system 200 according to one or more embodiment of the disclosure. The monitoring system 200 comprises a reflector 210 positioned above a transfer robot 114 in a transfer station 110 of the processing tool 100. The transfer robot 114 has a end effector 114a that is sized to extend between a wafer 220 and a substrate support 230 when the wafer 220 is lifted on lift pins 240.

The reflector 210 can be any suitable reflector known to the skilled artisan and is not limited to mirror-type reflections. The reflector 210 of some embodiments comprises one or more of a mirror, lens, aperture or collimator. The reflector 210 is configured to direct radiant energy 205 from a processing chamber 130 connected to the transfer station 110 to a camera 250 above the transfer station 110. The camera 250 is configured to measure infrared radiation (radiant energy 205) from the processing chamber 130.

The camera 250 can be any suitable image collection device known to the skilled artisan. In some embodiments, the camera 250 is a forward looking infrared (FLIR) device. The camera 250 of some embodiments comprises a charge coupled device (CCD) for collecting an image of the processing chamber 130 through an open slit valve (port 176).

The camera 250 of some embodiments is mounted outside of the transfer station 110 and the transfer station 110 comprises a viewport 111. The viewport 111 can be any suitable component that is transparent to the radiation wavelengths being monitored, measured, or imaged by the camera 250. The reflector 210 and camera 250 are aligned with the viewport 111.

In some embodiments, the reflector 210 is connected to the ceiling 110a of the transfer station 110 with a reflector bracket 212. In some embodiments, the reflector bracket 212 holds the reflector 210 in a fixed position aligned with the processing chamber 130. In some embodiments, the reflector bracket 212 holds the reflector 210 on a pivotable connection to allow the reflector 210 to be angled in different directions.

In some embodiments, there is one reflector 210 and one camera 250 for each processing chamber 130. In some embodiments, there are a plurality of reflectors 210 with each reflector aligned with a different processing chamber connected to the transfer station 110. For example, in the embodiment illustrated in FIG. 1, in some embodiments, transfer station 110 has four reflectors, with each reflector aimed at one of processing chambers 124, 126, 128, 130. In some embodiments, each of the plurality of reflectors 250 are aligned with a single camera 250. In some embodiments, each of the plurality of reflectors 250 is aligned with a separate camera 250 to measure infrared radiation from a processing chamber. In some embodiments, the reflector is mounted to the transfer robot so that whichever direction the robot is facing, the monitoring system remains aligned, allowing a single camera and reflector to be used with multiple processing chambers.

Some embodiments of the monitoring system 200 include a controller 190 operatively connected to the camera 250, and an interlock 260. The controller 190 can be the same controller as the system controller in FIG. 1 which controls the processing tool 100, or a separate controller that is configured to operate an interlock 260 in the event that the controller 190 determines that there is an issue that needs to be addressed before further processing in any individual processing chamber 130.

The controller of some embodiments is configured to evaluate an image taken by the camera 250 to determine one or more of a wafer position within the processing chamber 130 or positions of the lift pins 240 in the processing chamber 130.

In use, the monitoring system 200 takes an image of the interior of the processing chamber 130 when the port 176 is open before the transfer robot 114 engages with the wafer 220 or lift pins 240 in the processing chamber 130. The controller 190 evaluates the image from the camera 250 to determine if the processing chamber 130 is in an operational state or in a failure state. If the processing chamber 130 is in an operational state, the processing tool controller continues with the expected use of the processing chamber 130. However, if the controller determines that the processing chamber 130 is in a failure state, the controller 190 activates the interlock 260 which prevents the transfer robot 114 from entering the processing chamber 130 and indicates the failure to the user to manually confirm the failure state and make any necessary repairs.

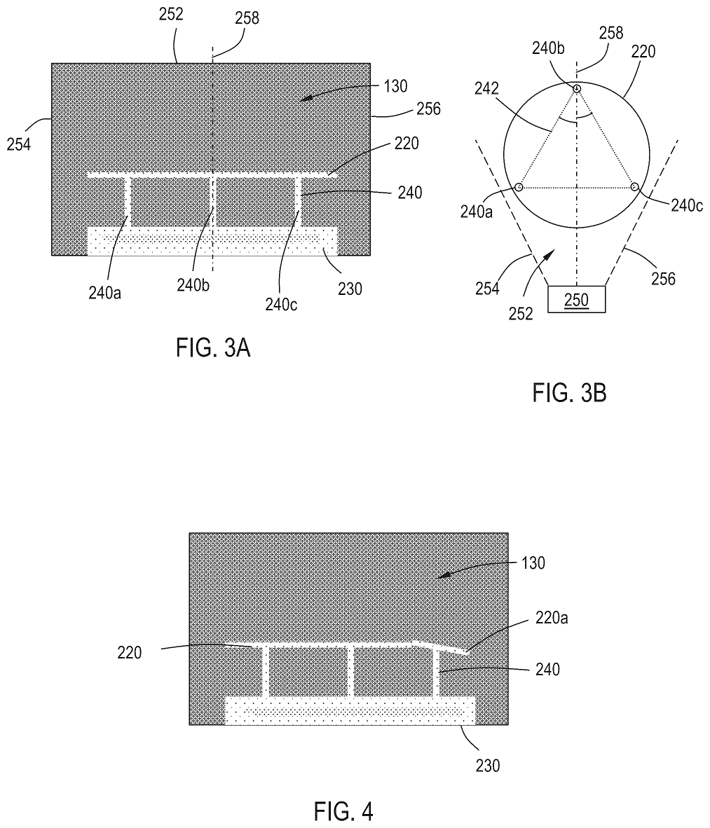

FIGS. 3A through 8B illustrate exemplary images recorded by the camera 250 in accordance with one or more embodiment of the disclosure. FIG. 3A illustrates a temperature profile map showing the interior of the processing chamber 130 with the wafer 220, substrate support 230 and lift pins 240 within the field of view 252 of the camera 250. FIG. 3B illustrates a schematic representation of the processing chamber 130 with the wafer 220 and lift pins 240 within the field of view 252 of the camera 250. The field of view 252 of the camera 250 illustrated shows the left edge 254 of the field of view 252 and the right edge 256 of the field of view 252 in dashed lines, with the center 258 of the field of view 252 in a dash-dot line. For illustrative purposes, the embodiment shown in FIGS. 3A and 3B have the lift pins 240 arranged in an equilateral triangular formation that is centered and symmetrical with respect to the field of view 252 so that the center 258 of the field of view 252 is aligned with the center lift pin 240b and the imaginary line representing the center 258 of the field of view 252 bisects the triangular pattern 242 formed by the three lift pins 240.

FIG. 3A shows the processing chamber 130 in the operational state with the wafer 220 spaced from the substrate support 240 by the lift pins 240 with the wafer 220 being flat, indicating that there is no warpage or breakage of the wafer, and all three lift pins 240 extending about the same distance from the substrate support and in contact with the wafer 220, indicating that the lift pins 240 are operable and not sticking within the substrate support.

FIGS. 4 through 8B show various failure states that can be determined by the controller 190 from the image recorded by the camera 250. FIG. 4 illustrates a broken wafer 220, showing a mis-aligned or sagging portion of the wafer 220a. The image analyzed by the monitoring system 200 for this embodiment would be considered a failure state, causing the interlock 260 to be activated.

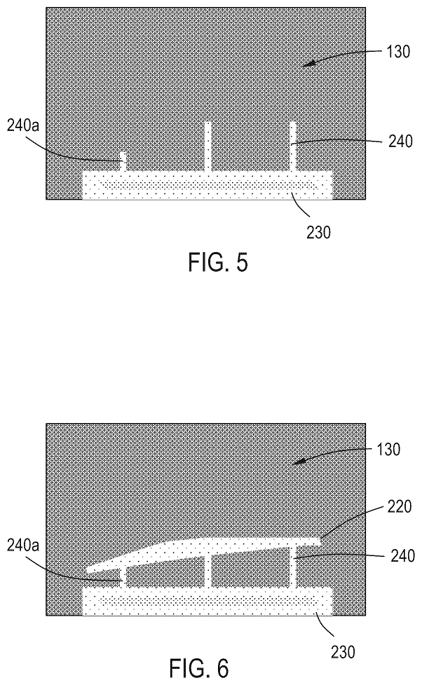

FIG. 5 shows a failure state embodiment in which one of the lift pins 240a is either broken or did not fully extend from the substrate support 230. In this embodiment, the wafer 220 is omitted to illustrate the failure state. Again, the interlock 260 would be activated, preventing a wafer from being loaded into the processing chamber 130.

FIG. 6 shows a similar issue to that of FIG. 5 with the wafer 220 included. In this embodiment, the wafer was partially lifted off of the substrate support, causing a tilting of the wafer 220 by the lift pin 240a. The odd shape of the wafer 220 in this image is due to the two dimensional image of the three dimensional object, as will be understood by the skilled artisan. The monitoring system 200 would consider the atypical temperature profile of the image as indicating the failure state and activating the interlock 260.

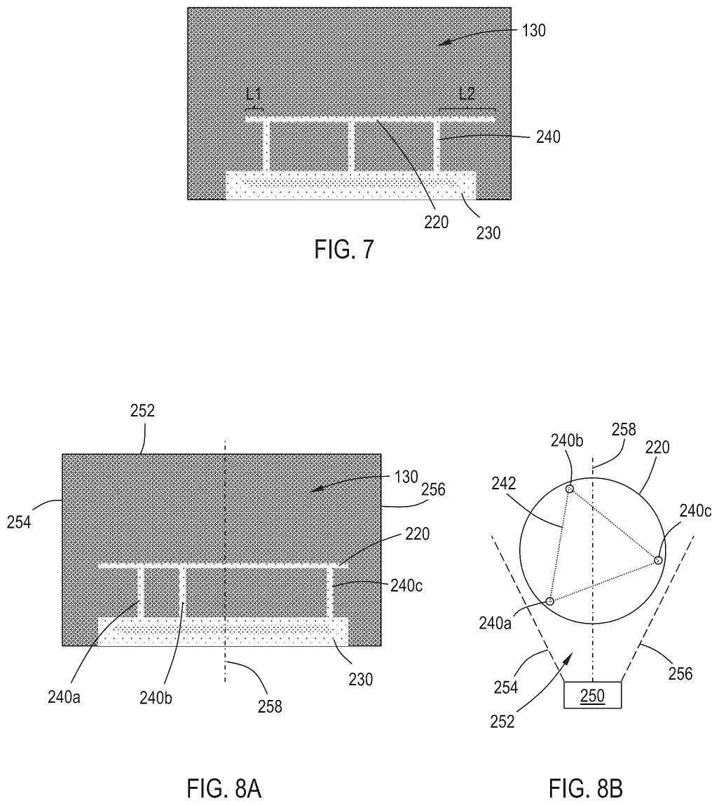

FIG. 7 shows another failure state in which the wafer 220 is not centered on the substrate support 230. The image recorded by the camera 250 in some embodiments is analyzed to ensure that the wafer 220 is centered on the substrate support 230. In the illustrated embodiment, the lift pins 240 are illustrated as being equally spaced and centered on the substrate support 230. In the embodiment shown, the monitoring system 200 can determine the amount of substrate 220 that extends beyond the bounds of the lift pins 240. For example, the monitoring system 200 can determine the length L1 of the wafer 220 overhang on the left side and the length L2 of the wafer 220 overhang on the right side of the field of view, relative to the outer lift pins 240. In the simplified example shown in FIG. 7, if the length L1 and length L2 are equal, then the wafer 220 is considered centered. If the length L1 is different than the length L2, as illustrated, then the wafer 220 is considered to be off-center and the monitoring system 200 would consider the image to indicate a failure state and activate the interlock 260.

The embodiments illustrated in FIGS. 4 through 7 show the lift pins 240 centered on the substrate support 230 and symmetrical around the center lift pin 240 so that the spacing between the left lift pin and the right lift pin relative to the center lift pin are the same, as illustrated in FIG. 3B. In an embodiment with three lift pins 240, the lift pins 240 are arranged in a triangular pattern 242. If the triangular pattern 242 is an equilateral triangle, then this arrangement can occur when the field of view 252 of the camera 250 is centered on the center lift pin 240b and the imaginary center 258 line from the camera 250 to the center lift pin 240b bisects the equilateral triangle 242.

The skilled artisan will recognize that the lift pins 240 can be arranged in a triangular pattern 242 other than an equilateral triangle, asymmetrical with the center 258 of the field of view 252 of the camera 250, and/or uncentered with the center 258 of the field of view 252 of the camera 250. FIG. 8A illustrates another embodiment in which the lift pins 240 are arranged in the field of view 252 so that the two-dimensional image is asymmetrical with respect to the center 258 of the field of view 252 and none of the lift pins 240 are aligned with the center 258 of the field of view 252. FIG. 8B shows a schematic representation of a top view of the processing chamber imaged in FIG. 8A. In this embodiment, the left lift pin 240a and center lift pin 240b are to the left of the center 258 of the field of view 252 while the right lift pin 240c is to the right of the center 258 of the field of view 252. The right lift pin 240c is also illustrated closer to the edge of the wafer 220 than the left lift pin 240a as a result of the orientation of the triangular pattern 242 formed by the lift pins. In embodiments of this sort, the monitoring system 200 is configured to include a range of acceptable values for one or more of: the left edge of the wafer 220 to left lift pin 240a distance; the left lift pin 240a to center lift pin 240b distance; the center lift pin 240b to right lift pin 240c distance; or the right lift pin 240c to right edge of the wafer 220 distance. Any or all of these parameters can be used to determine whether the wafer 220 is off-center or broken so that a failure state can be detected and the interlock activated.

The embodiments illustrated in FIGS. 2 through 8B show examples in which there are three lift pins 240. The skilled artisan will recognize that the disclosure is not limited to embodiments with three lift pins 240. In some embodiments, there are two lift pins (where at least one contacts the wafer 220 at more than one point), four lift pins, 5 lift pins or six lift pins. The skilled artisan will recognize the variations in the infrared images that can arise from different arrangements and numbers of lift pins.

The controller 190 of the monitoring system 200 of some embodiments including a machine learning algorithm. As the temperature mapping recorded as infrared radiation emitted from the substrate support, lift pins, wafer and processing chamber interior indicates an operational state, the machine learning algorithm adds the profile parameters to a database to learn and refine the acceptable profiles for an operational state.

One or more embodiments of the disclosure are directed to methods of preventing damage to a transfer robot, or processing chamber. The methods comprise taking or recording an infrared image of a processing chamber interior. The image of the processing chamber includes a wafer and lift pins within the field of view of the camera. The image may also include at least a portion of the substrate support.

The infrared image recorded by the monitoring system is based on the emitted infrared radiation from the hot components and wafer. The wafer, substrate support and lift pins are at a greater temperature than the chamber interior due to the closeness to the heating element within the substrate support. The recorded image is a temperature gradient based on the emitted radiation and with a sufficient difference in temperature between the wafer and/or lift pins relative to the chamber interior, the different components can be distinguished by the monitoring system. In some embodiments, the temperature difference between the wafer and/or lift pins and the chamber interior is greater than or equal to 5° C., 10° C., 15° C., 20° C., or 25° C.

The image is evaluated to determine if the processing chamber is in an operational state or a failure state based on the emitted radiation from the wafer and lift pins. Image processing software can be used to perform a pattern recognition of the wafer and lift pins within the processing chamber and compared the a database which maintains a record of operational state parameters and/or failure state parameters that may be measured from the image.

If the processing chamber is determined to be in a failure state, according to some embodiments, the monitoring system activates an interlock that prevents the transfer robot from reaching into the processing chamber and potentially damaging the transfer robot.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A monitoring system for a semiconductor manufacturing processing tool, the monitoring system comprising:
a reflector positioned above a transfer robot in a transfer station of the processing tool, the reflector configured to direct radiant energy from a processing chamber connected to the transfer station to a camera above the transfer station, the camera configured to measure infrared radiation from the processing chamber.

2. The monitoring system of claim 1, wherein the camera is mounted outside of the transfer station and the transfer station comprises a viewport, the reflector and camera aligned with the viewport.

3. The monitoring system of claim 1, wherein the reflector is connected to the ceiling of the transfer station with a reflector bracket.

4. The monitoring system of claim 3, wherein the reflector bracket holds the reflector in a fixed position aligned with the processing chamber.

5. The monitoring system of claim 4, wherein there are a plurality of reflectors, each reflector aligned with a different processing chamber connected to the transfer station.

6. The monitoring system of claim 5, wherein there are a plurality of cameras positioned above the transfer station, each camera aligned with a reflector to measure infrared radiation from a processing chamber.

7. The monitoring system of claim 1, further comprising a controller operatively connected to the camera, and an interlock connected to the controller.

8. The monitoring system of claim 7, wherein the controller is configured to evaluate an image taken by the camera to determine one or more of a wafer position within the processing chamber or positions of the lift pins in the processing chamber.

9. The monitoring system of claim 8, wherein the controller is further configured to activate the interlock if a failure state in the processing chamber is detected, the failure state comprising one or more of a mis-aligned wafer, a broken wafer or a broken lift pin.

10. The monitoring system of claim 9, wherein activating the interlock stops the robot from entering the processing chamber.

11. The monitoring system of claim 9, wherein the controller has a machine learning algorithm configured to learn when an image taken by the camera is in the failure state or an operational state.

12. The monitoring system of claim 1, wherein the reflector is mounted to transfer robot to reflect light from any direction the transfer robot faces.

13. A monitoring system for a semiconductor manufacturing processing tool, the monitoring system comprising:
a reflector and reflector bracket connected to a ceiling of a transfer station positioned above a transfer robot in the transfer station of the processing tool, the reflector configured to direct radiant energy from a processing chamber connected to the transfer station to a camera mounted above and outside of the transfer station, the camera configured to measure infrared radiation from the processing chamber through a viewport in the ceiling of the transfer station, the reflector bracket holding the reflector in a fixed position aligned with the processing chamber.

14. The monitoring system of claim 13, wherein there are a plurality of reflectors, each reflector aligned with different processing chambers connected to the transfer station, and a plurality of cameras positioned above the transfer station, each camera aligned with a reflector to measure infrared radiation from one of the processing chambers.

15. The monitoring system of claim 13, further comprising a controller operatively connected to the camera, and an interlock connected to the controller, the controller having one or more configurations selected from: a configuration to evaluate an image taken by the camera to determine one or more of a wafer position within the processing chamber or positions of the lift pins in the processing chamber; and a configuration to activate the interlock if a failure state in the processing chamber is detected, the failure state comprising one or more of a mis-aligned wafer, a broken wafer or a broken lift pin, wherein activating the interlock stops the robot from entering the processing chamber.

16. The monitoring system of claim 15, wherein the controller has a machine learning algorithm configured to learn when an image taken by the camera is in the failure state or an operational state.

17. A method of preventing damage to a transfer robot of a processing chamber, the method comprising:
taking an infrared image of a processing chamber interior, the image including a wafer and lift pins;
evaluating the image to determine if the processing chamber is in an operational state or a failure state from the image of the wafer and lift pins; and
activating an interlock if the processing chamber is determined to be in a failure state.

18. The method of claim 17, wherein the infrared image shows a temperature differential between the wafer and/or lift pins relative to the processing chamber interior that is greater than or equal to 5° C.

19. The method of claim 17, wherein the infrared image is taken using a camera located outside of a transfer station via a reflector positioned within the transfer station aligned with the processing chamber.

20. The method of claim 17, further comprising adding image parameters of an image determined to be in the operational state to an image analysis database.
